(19) United States
(12) Patent Application Publication
(10) Pub. No.: US 2026/0206253 A1
(43) Pub. Date: Jul. 16, 2026

(54) SEMICONDUCTOR DEVICE HAVING CHANNEL LAYERS WITH DIFFERENT THICKNESSES FOR IMPROVED PERFORMANCE AND METHOD OF MANUFACTURING THEREOF

(71) Applicant: Taiwan Semiconductor Manufacturing Company, Ltd., Hsinchu (TW)

(72) Inventors: Ta-Chun LIN, Hsinchu (TW); Pin Chun SHEN, Hsinchu (TW); Chih-Hao CHANG, Hsinchu (TW); Jhon Jhy LIAW, Hsinchu (TW)

(73) Assignee: Taiwan Semiconductor Manufacturing Company, Ltd., Hsinchu (TW)

(21) Appl. No.: 19/178,012

(22) Filed: Apr. 14, 2025

Related U.S. Application Data
(60) Provisional application No. 63/744,987, filed on Jan. 14, 2025.

(51) Int. Cl. H10D 30/00; H10D 30/01

(52) U.S. Cl. CPC H10D 30/506; H10D 30/0194; H10D 30/0198

(57) ABSTRACT

A method of manufacturing a semiconductor device includes alternately depositing sacrificial layers and channel layers over a substrate, such that a second channel layer below a first channel layer is thinner than the first channel layer, patterning the semiconductor stack to form a fin, recessing the fin to form a source/drain opening, and epitaxially depositing a semiconductor material in the source/drain opening to form a source/drain structure. The method further includes removing the sacrificial layers such that surfaces of the channel layers are exposed, depositing a gate dielectric over the surfaces of the channel layers and a conductive material over the gate dielectric to form a gate electrode wrapping around the channel layers, and depositing an electrically conductive material over the source/drain structure in the source/drain opening to form a source/drain contact having a bottom surface that is lower than a bottom surface of the first channel layer.

### CROSS-REFERENCE TO RELATED APPLICATION

This application claims priority to U.S. Provisional Application No. 63/744,987, filed on Jan. 14, 2025, the entire disclosure of which is incorporated herein by reference.

### BACKGROUND

As the semiconductor industry advances into nanometer-scale technology nodes, driven by the need for higher device density, enhanced performance, and reduced costs, it has faced significant fabrication and design challenges. These challenges have led to the adoption of three-dimensional structures, such as multi-gate field-effect transistors (FETs), including fin field-effect transistors (FinFETs), gate-all-around field-effect transistors (GAA-FETs), forksheet transistors, and complementary FETs (CFET). In a FinFET, for example, the gate electrode interfaces with three sides of the channel region, separated by a gate dielectric layer. This configuration effectively provides control over the current flow through the channel, as the gate wraps around three of the channel's surfaces. However, the fourth side, which forms the bottom of the channel, remains distant from the gate electrode and thus experiences less effective gate control. In contrast, a GAA-FET features a gate electrode that surrounds all sides of the channel region, enabling more comprehensive depletion of the channel and resulting in reduced short-channel effects due to a steeper subthreshold swing and lower drain-induced barrier lowering. As transistor dimensions continue to shrink, further advancements in GAA-FET technology are necessary to meet the increasing demands of modern semiconductor devices.

### BRIEF DESCRIPTION OF THE DRAWINGS

The present disclosure is best understood from the following detailed description when read with the accompanying figures. It is emphasized that, per the standard practice in the industry, various features are not drawn to scale and are used for illustration purposes only. The dimensions of the various features may be arbitrarily increased or reduced for clarity of discussion.

FIG. 1A is a first vertical cross-sectional view of a semiconductor device configured as a gate-all-around field-effect transistor (GAA FET), according to various embodiments.

FIG. 1B is a second vertical cross-sectional view of the semiconductor device of FIG. 1A, according to various embodiments.

FIG. 2 is a vertical cross-sectional view of a structure used in forming a semiconductor device, according to various embodiments.

FIG. 3 is a vertical cross-sectional view of a structure used in forming a semiconductor device, according to various embodiments.

FIG. 4 is a vertical cross-sectional view of a structure used in forming a semiconductor device, according to various embodiments.

FIG. 5 is a vertical cross-sectional view of a structure used in forming a semiconductor device, according to various embodiments.

FIG. 6 is a vertical cross-sectional view of a structure used in forming a semiconductor device, according to various embodiments.

FIG. 7 is a vertical cross-sectional view of a structure used in forming a semiconductor device, according to various embodiments.

FIG. 8 is a vertical cross-sectional view of a structure used in forming a semiconductor device, according to various embodiments.

FIG. 9A is a vertical cross-sectional view of a structure used in forming a semiconductor device, according to various embodiments.

FIG. 9B is a vertical cross-sectional view of a semiconductor device formed from the structure of FIG. 9A, according to various embodiments.

FIG. 9C is a vertical cross-sectional view of a structure used in forming a semiconductor device, according to various embodiments.

FIG. 9D is a vertical cross-sectional view of a semiconductor device formed from the structure of FIG. 9C, according to various embodiments.

FIG. 10A is a vertical cross-sectional view of a semiconductor device having two channel layers, according to various embodiments.

FIG. 10B is a vertical cross-sectional view of a semiconductor device having two channel layers, according to various embodiments.

FIG. 11A is a vertical cross-sectional view of a semiconductor device having four channel layers, according to various embodiments.

FIG. 11B is a vertical cross-sectional view of a semiconductor device having four channel layers, according to various embodiments.

FIG. 11C is a vertical cross-sectional view of a semiconductor device having four channel layers, according to various embodiments.

FIG. 12A is a vertical cross-sectional view of a structure used in forming a semiconductor device having a backside contact, according to various embodiments.

FIG. 12B is a vertical cross-sectional view of a semiconductor device formed from the structure of FIG. 12A, according to various embodiments.

FIG. 13 is a flowchart illustrating operations of a method of manufacturing a semiconductor device, according to various embodiments.

FIG. 14 is a flowchart illustrating operations of a method of manufacturing a semiconductor device, according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

One or more of the disclosed embodiments advantageously discloses methods of manufacturing a semiconductor device having increased source/drain conductivity, reduced short-channel effects, and reduced drain-induced barrier lowering effects. In this regard, an embodiment semiconductor device is configured as a gate-all-around transistor structure in which a source/drain contact is formed in a source/drain epitaxial layer such that the source/drain contact has a bottom surface that is lower than a bottom surface of one or more channel layers. The semiconductor device further includes a heavily doped region formed below the bottom surface of the source/drain contact. Configuring the source/drain contact and the heavily doped region in this way increases the source/drain conductivity and thus reduces ohmic loss and RC delay. To avoid short-channel effects and drain-induced barrier lowering effects, a channel layer that is closest to the heavily doped region and/or closest to the bottom surface of the source/drain contact is chosen to have a thickness that is smaller than that of other channel layers.

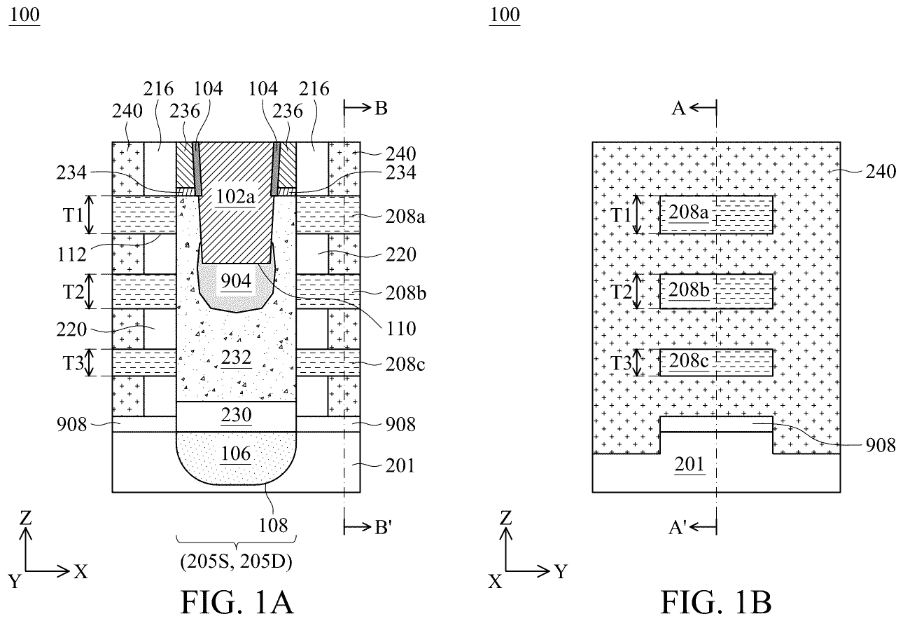

FIG. 1A is a first vertical cross-sectional view of a portion of a semiconductor device 100 configured as a gate-all-around field-effect transistor (GAA-FET) device, and FIG. 1B is a second vertical cross-sectional view of the semiconductor device 100 of FIG. 1A, according to various embodiments. The cross-sectional plane that defines the view of FIG. 1A lies in the X-Z plane and is indicated by the cross-section A-A′ in FIG. 1B. Similarly, the cross-sectional plane that defines the view of FIG. 1B lies in the Y-Z plane and is indicated by the cross-section B-B′ in FIG. 1A.

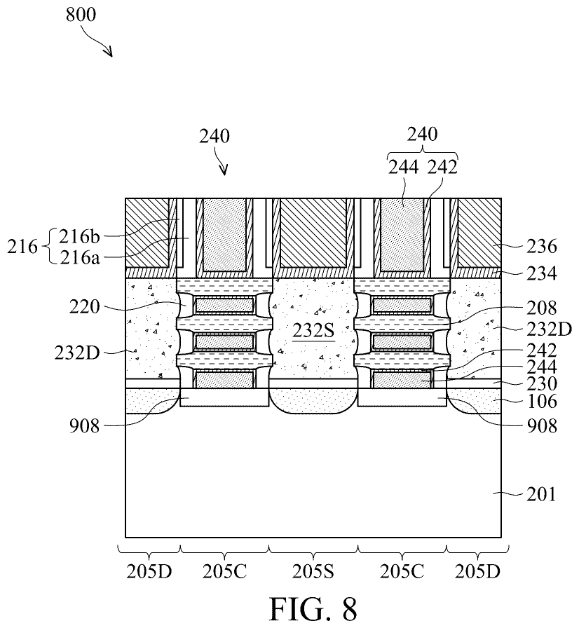

The semiconductor device 100 includes a plurality of semiconductor nanostructure layers (e.g., nanosheets or nanowires) each configured as a channel layer (208a, 208b, 208c). The semiconductor device 100 further includes a gate structure 240 that surrounds a portion of each channel layer (208a, 208b, 208c). As described in greater detail with reference to FIG. 8, below, the gate structure 240 further includes an electrically conductive material that forms a gate electrode layer 244 separated from the plurality of channel layers (208a, 208b, 208c) by a gate dielectric layer 242 (not shown in FIGS. 1A and 1B).

The plurality of channel layers (208a, 208b, 208c) have respective thicknesses (T1, T2, T3). According to various embodiments, a first thickness T1 of a first channel layer 208a is thicker than a second thickness T2 of a second channel layer 208b. The choice of different channel thicknesses is used to reduce drain-induced barrier lowering (DIBL) and short-channel effects, as described in greater detail below.

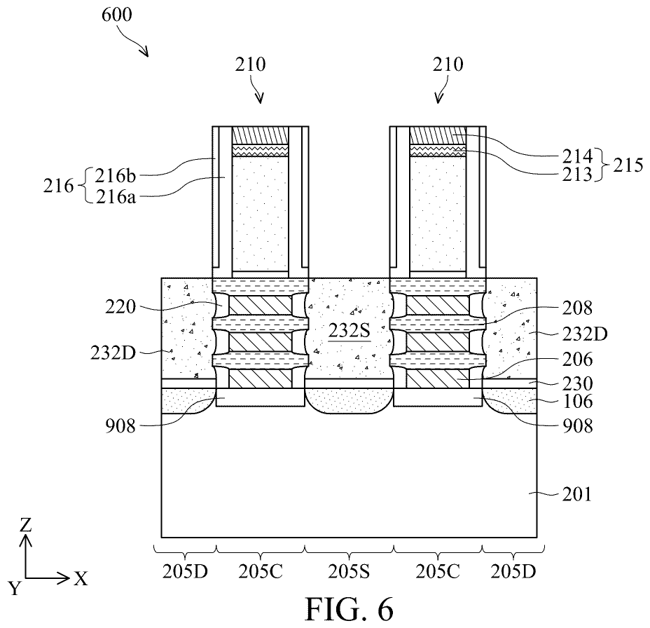

The semiconductor device 100 further includes an epitaxial source/drain feature 232 formed in contact with ends of each of the plurality of channel layers (208a, 208b, 208c). As described in greater detail with reference to FIG. 6, below, the source/drain feature 232 is configured as a source feature 232S in a source region 205S of the semiconductor device 100 and is configured as a drain feature 232D in a drain region 205D of the semiconductor device 100. According to certain embodiments, the source feature 232S and the drain feature 232D (e.g., see FIG. 6) are similar structures and are referred to collectively as source/drain features 232. In other embodiments, the source feature 232S and the drain feature 232D have dissimilar structures and compositions.

According to various embodiments, the semiconductor device 100 is formed over a semiconductor substrate 201. In this regard, according to certain embodiments the plane of the FIG. 1A intersects the semiconductor substrate 201 along a longitudinal direction (i.e., along the crystallographic direction of the source/drain feature 232). Various other substrate orientations are provided in other embodiments. As shown in FIG. 1A, the semiconductor device 100 includes a first epitaxial semiconductor layer 106 formed in a source/drain trench 108 and an isolation dielectric layer 230 formed between the first epitaxial layer 106 and the source/drain feature 232, which itself is a second epitaxial layer. As described in greater detail below, the first epitaxial layer 106 is undoped and the source/drain feature 232 is a doped epitaxially-deposited semiconductor material. According to certain embodiments, a second isolation dielectric layer 908 is also formed between gate structure 240 and the substrate 201.

As shown in FIG. 1A, the semiconductor device 100 includes inner spacer features 220 formed between the gate structure 240 and the source/drain feature 232. In some embodiments, the inner spacer features 220 are made of a dielectric material, such as a silicon-containing dielectric material, including but not limited to silicon oxide, silicon nitride, silicon carbide, silicon oxynitride, silicon carbon nitride, silicon oxy carbonitride, and/or oxygen-doped silicon carbonitride. In some embodiments, the inner spacer features 220 are formed of a low dielectric constant (low-k) material. For example, in some embodiments, the dielectric constant (k) values of the inner spacer features 220 are lower than that of silicon oxide, such as below 4.2, equal to or lower than about 3.9, or within a range from about 3.5 to about 3.9.

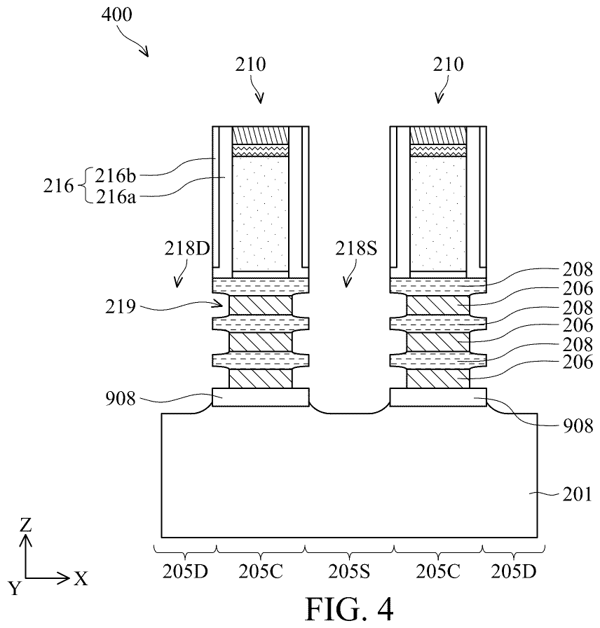

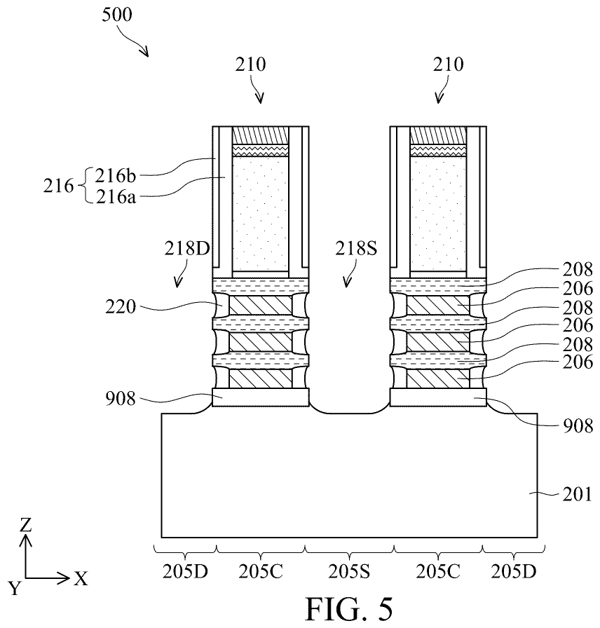

In some embodiments, the inner spacer features 220 are formed by a deposition process such as atomic layer deposition (ALD), chemical vapor deposition (CVD), such as plasma-enhanced chemical vapor deposition (PECVD), low-pressure chemical vapor deposition (LPCVD), or high aspect ratio process (HARP) CVD, another suitable technique, and/or a combination thereof. In some embodiments, an etching-back process is performed that includes an anisotropic etching process such as dry plasma etching, an isotropic etching process such as dry chemical etching, remote plasma etching, wet chemical etching, and/or a combination of these techniques, as described in greater detail with reference to FIGS. 4 and 5.

The semiconductor device 100 further includes a front contact 102a that includes an electrically conducting material that is coupled to the source/drain feature 232. The front contact 102a is configured as a source/drain contact having a bottom surface 110 that is lower than a bottom surface 112 of the first channel layer 208a. This configuration improves the conductive contact between the front contact 102a and the source/drain feature 232. In this regard, contact resistance is lowered which leads to an increase in device performance in the form of decreased resistive losses and reduced RC delays.

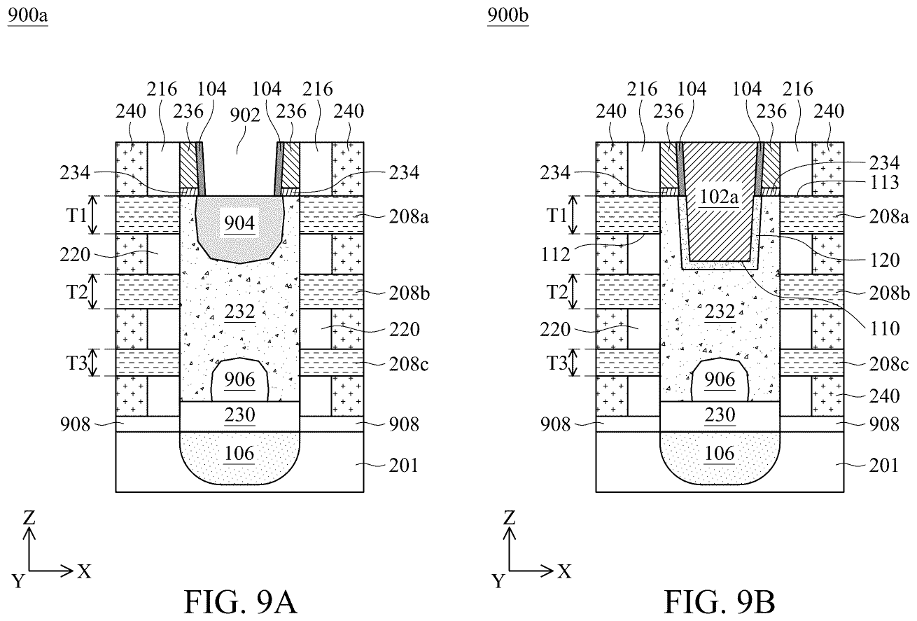

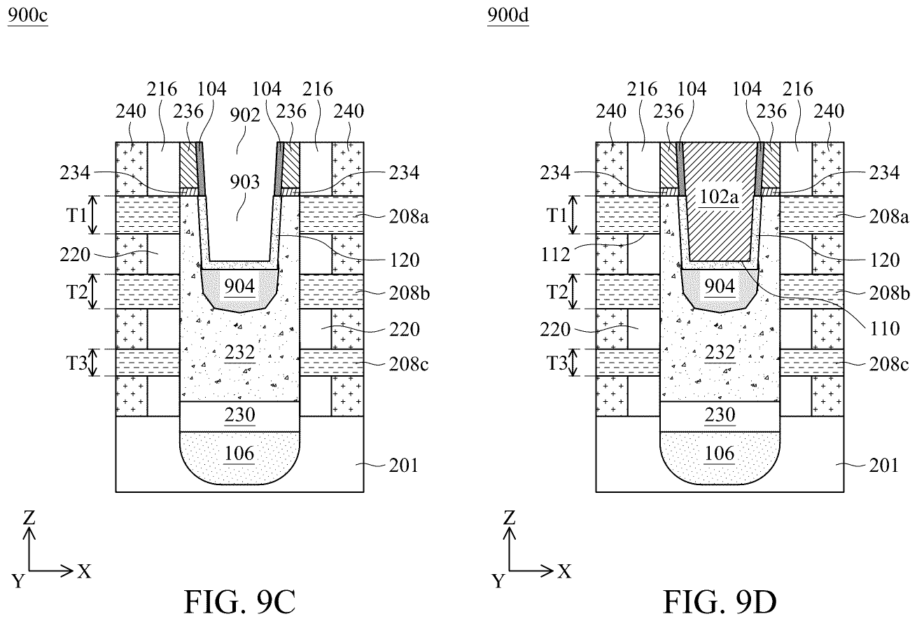

Placing the front contact 102a below the first channel layer 208a may introduce increased electric field strengths in the vicinity of the second channel layer 208b, which may lead to increased short-channel and DIBL effects. These effects are mitigated by decreasing the thickness T2 of the second channel layer 208b relative to the thickness T1 of the first channel layer 208a, as mentioned above, and as described in greater detail below. According to various embodiments, the front contact 102a is placed at various depths relative to the first channel layer 208a and the second channel layer 208b. In such embodiments, the channel layers 208 are configured to have different thicknesses such that conductivity of the source/drain contact 102 is improved and DIBL and short channel effects are reduced, as described in greater with reference to FIGS. 9A to 11C, below.

The gate structure 240 and the front contact 102a are formed within an interlayer dielectric (ILD) layer 236 (e.g., see FIG. 8), as described in greater detail below. The semiconductor device 100 further includes a contact etch stop layer 234 formed between the ILD layer 236 and the source/drain feature 232, as described in greater detail below. The semiconductor device 100 further includes a liner layer 104 separating the ILD layer 236 from the front contact 102a and gate spacer layers 216 separating the ILD layer 236 from the gate structure 240, as described in greater detail below.

According to various embodiments, the source/drain feature 232 is formed of doped semiconductor materials (e.g., silicon, SiGe, or the like), and the electrically conducting material of the front contact 102a is metallic. In other embodiments, a silicide layer 120 (e.g., see FIG. 9B) is formed between the source/drain feature 232 and the front contact 102a, as described in greater detail below.

According to various embodiments, the source/drain feature 232 is an epitaxial n-type doped semiconductor layer. For example, according to some embodiments, the source/drain feature 232 is an n-type doped silicon layer. In some embodiments, the source/drain feature 232 is doped with phosphorous having a dopant concentration that is between about 5×10¹⁹ atom/cm³ and about 1×10²² atom/cm. In other embodiments, the source/drain feature 232 is an epitaxial p-type doped semiconductor layer. For example, according to some embodiments, the source/drain feature 232 is a p-type doped SiGe alloy layer. In some embodiments, the source/drain feature 232 is a SiGe alloy layer having a composition SiₓGe₁₋ₓ, where x is between about 0.4 and about 0.6 In some embodiments, the source/drain feature 232 is doped with boron having a dopant concentration that is between about 5×10¹⁹ atom/cm³ and about 1×10²² atom/cm³.

In embodiments where the semiconductor device 100 is formed as an n-channel nanostructure device, such as an n-channel GAA FET, the source feature/drain feature 232 includes semiconductor materials such as silicon phosphide (SiP), silicon arsenide (SiAs), silicon carbide phosphide (SiCP), silicon carbide (SiC), silicon, gallium arsenide (GaAs), or another suitable semiconductor material, or a combination thereof. In some embodiments, the source/drain feature 232 is doped with an n-type dopant during the epitaxial growth process. For example, in certain embodiments, the n-type dopant is phosphorus or arsenic. In some embodiments, the source/drain feature 232 is epitaxially grown silicon doped with phosphorus to form silicon phosphide (SiP).

In embodiments where the semiconductor device 100 is formed as a p-channel nanostructure device, such as a p-channel GAA FET, the source/drain feature 232 is made of semiconductor materials such as SiGe, Si, gallium arsenide (GaAs), or another suitable semiconductor material, or a combination thereof. In some embodiments, the source/drain feature 232 is doped with a p-type dopant during the epitaxial growth process. For example, in certain embodiments, the p-type dopant is boron or boron difluoride (BF₂). In some embodiments, the source/drain feature 232 is epitaxially grown SiGe doped with boron to form SiGe source/drain features 232.

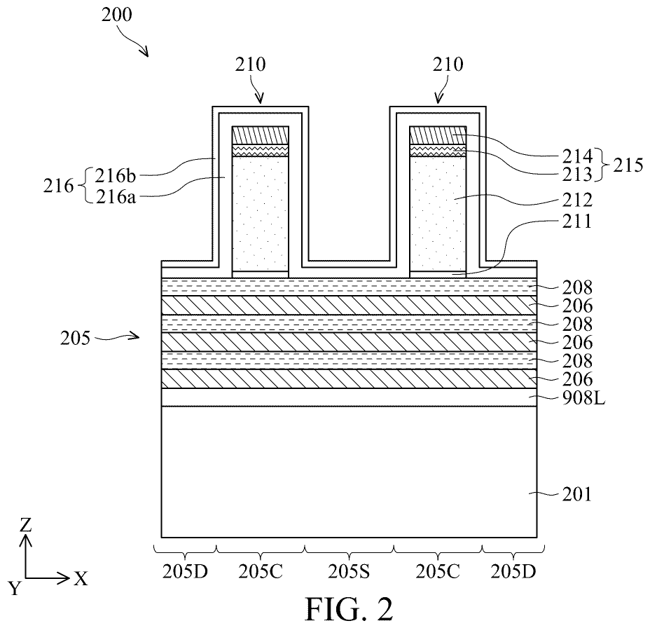

In some embodiments, the epitaxial growth process used to form the source/drain feature 232 is cyclic deposition etch epitaxy (CDE). CDE involves periodic deposition operations, where the semiconductor structure is exposed to a pulse of precursors for deposition and doping, followed by exposure to an etchant gas for a first period. This is followed by a second period during which the semiconductor device is exposed only to the etchant gas, without precursors. The process then repeats, with a third period during which the semiconductor device is again exposed to the precursor pulse for deposition and doping, followed by the etchant gas. This cycle is repeated until the desired thickness of the source/drain feature 232 is formed. Further details of the processing operations used to form the semiconductor device 100 are described in greater detail with reference to FIGS. 2 to 8, below.

FIG. 2 is a vertical cross-sectional view of a structure 200 that is used in the formation of a semiconductor device 100, according to various embodiments. The structure 200 includes a substrate 201. In an embodiment, the substrate 201 is a bulk silicon substrate (i.e., including bulk single-crystalline silicon). In other embodiments, the substrate 201 includes other semiconductor materials such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof, or other suitable materials. In some alternative embodiments, the substrate 201 is a semiconductor-on-insulator (SOI) substrate (not shown), such as a silicon-on-insulator (SOI) substrate, a silicon germanium-on-insulator (SGOI) substrate, or a germanium-on-insulator (GOI) substrate. Semiconductor-on-insulator substrates are fabricated using separation by implantation of oxygen (SIMOX), wafer bonding, and/or other suitable methods. In some embodiments, the semiconductor layer 204 is silicon, silicon germanium, germanium, or other suitable materials and is undoped or doped with a low dose of dopants.

The structure 200 includes a fin-shaped structure 205 disposed over the substrate 201. The fin-shaped structure 205 extends lengthwise along the X direction and is divided into channel regions 205C overlapped by sacrificial gate stacks 210 (as described below), source regions 205S, and drain regions 205D. In this example, two channel regions 205C, one source region 205S, and two drain regions 205D are shown in FIG. 2, but the structure 200 includes additional source/drain regions (205S, 205D) and channel regions 205C in other embodiments.

The fin-shaped structure 205 is formed from a portion of the substrate 201 and a vertical stack of alternating semiconductor layers (206, 208) using a combination of lithography and etch steps. An exemplary lithography process involves spin-on coating a photoresist layer, soft baking the photoresist layer, aligning a mask, exposing, post-exposure baking, developing the photoresist layer, rinsing, and drying (e.g., hard baking). In some instances, the patterning of the fin-shaped structure 205 uses double-patterning or multi-patterning processes to create patterns with pitches smaller than those otherwise obtainable using a single, direct photolithography process. The etching process includes dry etching, wet etching, and/or other suitable techniques.

In the depicted embodiment, the vertical stack of alternating semiconductor layers (206, 208) includes a plurality of channel layers 208 interleaved by a plurality of sacrificial layers 206. Each of the channel layers 208 consists of Si, and each of the sacrificial layers 206 consists of SiGe. The channel layers 208 and the sacrificial layers 206 are epitaxially deposited on the substrate 201 using molecular beam epitaxy (MBE), vapor-phase epitaxy (VPE), ultra-high vacuum CVD (UHV-CVD), and/or other suitable epitaxial growth processes.

While not shown in FIG. 2, an isolation feature surrounds the fin-shaped structure 205 to isolate it from adjacent fin-shaped structures (i.e., that are separated from one another along the Y direction). In some embodiments, the isolation feature is deposited in trenches that define the fin-shaped structure 205. These trenches extend through the channel layers 208 and sacrificial layers 206 and terminate in the substrate 201. The isolation feature also referred to as a shallow trench isolation (STI) feature, is formed using a dielectric material deposited over the structure 200 using techniques such as chemical vapor deposition (CVD), sub-atmospheric CVD (SACVD), flowable CVD (FCVD), physical vapor deposition (PVD), spin-on coating, and/or other suitable processes. The deposited dielectric material is planarized and recessed until the fin-shaped structure 205 rises above the isolation feature. The dielectric material for the isolation feature includes silicon oxide, silicon oxynitride, fluorine-doped silicate glass (FSG), a low-k dielectric, combinations thereof, and/or other suitable materials. As further shown in FIG. 2, according to certain embodiments, an isolation dielectric layer 908L is further provided between the substrate 201 and the lowest sacrificial layer 206.

As mentioned above, the structure 200 includes sacrificial gate stacks 210 disposed over channel regions 205C of the fin-shaped structure 205. The channel regions 205C and the sacrificial gate stacks 210 define source regions 205S and drain regions 205D, which are regions that are not vertically overlapped by the sacrificial gate stacks 210. Each channel region 205C is positioned between a source region 205S and a drain region 205D along the X direction. FIG. 2 illustrates two sacrificial gate stacks 210, but other embodiments of the structure 200 include additional sacrificial gate stacks 210.

In this embodiment, a gate replacement process (or gate-last process) is adopted where the sacrificial gate stacks 210 serve as placeholders for functional gate structures (e.g., the gate structures 240 shown in FIG. 1A). The sacrificial gate stack 210 includes a sacrificial dielectric layer 211, a sacrificial gate electrode layer 212 over the sacrificial dielectric layer 211, and a gate-top hard mask layer 215 over the sacrificial gate electrode layer 212. The sacrificial dielectric layer 211 includes silicon oxide, the sacrificial gate electrode layer 212 is made of polysilicon, and the gate-top hard mask layer 215 is a multi-layer that includes a silicon oxide layer 213 and a silicon nitride layer 214 formed on the silicon oxide layer 213. Suitable deposition, photolithography, and etching processes are used to form the sacrificial gate stack 210.

As shown in FIG. 2, the structure 200 includes a gate spacer layer 216 disposed over the structure 200. The gate spacer layer 216 includes a first gate spacer layer 216a and a second gate spacer layer 216b deposited conformally over the structure 200, covering the top surfaces and sidewalls of the sacrificial gate stacks 210 and the top surfaces of the fin-shaped structure 205. The term “conformally” describes a layer with a substantially uniform thickness over various regions. A dielectric constant of the second gate spacer layer 216b exceeds that of the first gate spacer layer 216a, and the second gate spacer layer 216b exhibits greater etch resistance compared to the first gate spacer layer 216a in some embodiments. The first gate spacer layer 216a includes silicon oxide, silicon oxycarbide, or a suitable low-k dielectric material in some embodiments. The second gate spacer layer 216b includes silicon carbonitride, silicon nitride, zirconium oxide, aluminum oxide, or a suitable dielectric material in some embodiments. The first gate spacer layer 216a and the second gate spacer layer 216b are deposited over the sacrificial gate stacks 210 using processes such as CVD, SACVD, FCVD, atomic layer deposition (ALD), PVD, or other suitable processes.

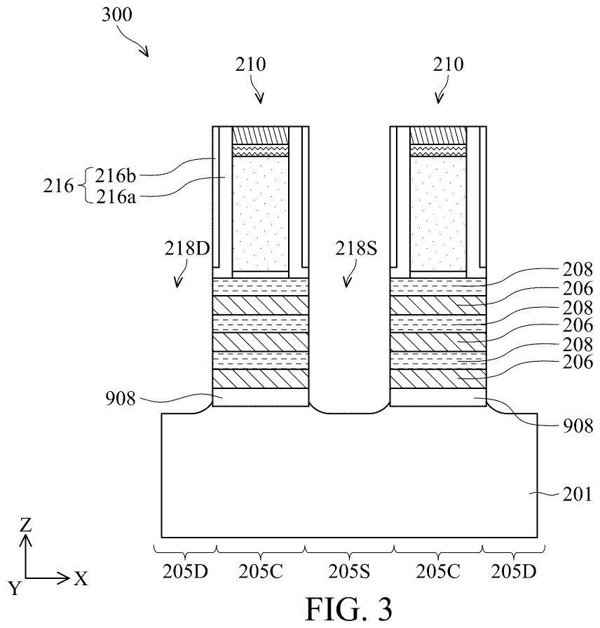

FIG. 3 is a vertical cross-sectional view of a structure 300 that is used in the formation of a semiconductor device 100a, according to various embodiments. The structure 300 is formed from the structure 200 by recessing a source region 205S and two drain regions 205D of the fin-shaped structure 205 to create a source opening 218S and two drain openings 218D, according to various embodiments. In some embodiments, the source region 205S and drain regions 205D of the fin-shaped structures not covered by the sacrificial gate stack 210 and the gate spacer layer 216 are anisotropically etched using a dry etching process or a suitable etching technique. A dry etching process utilizes oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, or combinations thereof. The source opening 218S and drain openings 218D extend through a vertical stack of channel layers 208 and sacrificial layers 206. These openings partially extend into the substrate 201. The sidewalls of the channel layers 208 and the sacrificial layers 206 are exposed within the source opening 218S and drain opening 281D, as shown in FIG. 3. As shown, the isolation dielectric layer 908L is also etched to generate the second isolation dielectric layer 908 described above with reference to FIGS. 1A and 1B.

Referring to FIGS. 4 and 5, inner spacer features 220 are formed after the creation of the source opening 218S and the drain opening 218D. Once the source opening 218S and the drain opening 218D are formed, the sacrificial layers 206 are exposed within these openings. As shown in FIG. 4, the sacrificial layers 206 are selectively and partially recessed to create inner spacer recesses 219, while the exposed channel layers 208 are not significantly etched. In an embodiment where the channel layers are made of silicon (Si) and the sacrificial layers 206 are made of silicon germanium (SiGe), the selective and partial recessing of the sacrificial layers 206 involves a selective isotropic etching process, which can include either a selective dry etching process or a selective wet etching process. The extent of recessing is controlled by the duration of the etching process. After forming the inner spacer recesses, an inner spacer material layer is deposited over the structure, including within the recesses. The inner spacer material layer includes silicon oxide, silicon nitride, silicon oxycarbide, silicon oxycarbonitride, silicon carbonitride, metal nitride, or another suitable dielectric material. The deposited inner spacer material layer is then etched back to remove excess material from the sidewalls of the channel layers 208, thereby forming the inner spacer features 220, as shown in FIG. 5. In some embodiments, the etch-back process is a dry etching process, similar to that used for forming the source opening 218S and the drain opening 218D.

FIG. 6 is a vertical cross-sectional view of a structure 600 that is used in the formation of a semiconductor device 100, according to various embodiments. As shown in FIG. 6, a source feature 232S is formed in the source opening 218S, and drain features 232D are formed in the drain opening 218D. Before the formation of the source feature 232S and the drain features 232D, a first epitaxial layer 106 is deposited in the source opening 218S and the drain openings 218D an isolation dielectric layer 230 is formed over the first epitaxial layer 106 at the bottom of the source opening 218S and the bottom of the drain opening 218D. As described above, the first epitaxial layer 106 is an undoped semiconductor layer, such as undoped Si or other suitable semiconductor material.

The isolation dielectric layer 230 is a dielectric layer and is referred to as a “flexible bottom isolation” structure in some embodiments. The isolation dielectric layer 230 reduces or substantially prevents current leakage between the source feature 232S, the drain feature 232D, and the substrate 201, or additional features to be formed at the backside of the structure 200. In some embodiments, the isolation dielectric layer 230 includes a silicon oxide, a silicon nitride, SiCN, SiCON, SiOC, SiC, or other suitable materials and is formed by oxidation (e.g., to form silicon oxide) or by a conformal deposition process followed by further processing, as follows.

The isolation dielectric layer 230 is formed by performing one or more conformal film deposition processes, such as plasma-enhanced atomic layer deposition (PEALD) or PECVD, followed by a film treatment process, such as etching back. The resulting conformal thin film inherits the shape of the underlying structure upon which it is formed. The film deposition process employs a cyclic PEALD method with reaction gases such as dichlorosilane (DCS) and ammonia/argon (NH₃/Ar) plasma. The subsequent film treatment process uses argon/nitrogen (Ar/N₂) plasma for etching.

In some embodiments, the first epitaxial layer 106 is formed as an epitaxial semiconductor feature that is epitaxially and selectively formed over the exposed top surfaces of the substrate 201 using an epitaxial process, such as molecular beam epitaxy (MBE), vapor-phase epitaxy (VPE), ultrahigh-vacuum chemical vapor deposition (UHV-CVD), metal-organic chemical vapor deposition (MOCVD), or other suitable epitaxial growth processes. In such embodiments, the bottom surface of the first epitaxial layer 106 generally follows the shape of the bottom surface of the source and drain openings (218S, 218D). Since the surfaces of the inner spacer features 220 are not conducive to epitaxial deposition, the first epitaxial layer 106 forms in a bottom-up fashion from the exposed surface of the substrate 201 of the substrate 201. In cross-section, the first epitaxial layer 106 exhibits a curved bottom shape and a flat top shape in the illustrated embodiment. Depending on the conductivity type of the source feature 232S, the first epitaxial layer 106 includes different compositions. For an n-type source feature 232S, the first epitaxial layer 106 includes undoped silicon (Si), and for a p-type source feature 232S, the isolation dielectric layer 230 includes undoped silicon germanium (SiGe) in some embodiments.

The source feature 232S and the drain feature 232D are formed over the isolation dielectric layer 230 using an epitaxial process, such as vapor-phase epitaxy (VPE), ultrahigh-vacuum chemical vapor deposition (UHV-CVD), molecular beam epitaxy (MBE), or other suitable processes. The epitaxial process uses gaseous and/or liquid precursors that interact with the composition of the isolation dielectric layer 230. The source feature 232S and the drain feature 232D are coupled to the channel layers 208 in the channel regions 205C of the fin-shaped structure 205. Depending on the conductivity type of the transistor being formed, the source feature 232S and the drain feature 232D are n-type and p-type source/drain features, respectively.

Exemplary n-type source/drain features include silicon, phosphorus-doped silicon, arsenic-doped silicon, antimony-doped silicon, or other suitable materials, and these may be in-situ doped during the epitaxial process by introducing an n-type dopant, such as phosphorus, arsenic, antimony, or ex-situ doped using a ion implantation process. Exemplary p-type source/drain features include germanium, gallium-doped silicon germanium, boron-doped silicon germanium, or other suitable materials, and these may be in-situ doped during the epitaxial process by introducing a p-type dopant, such as boron or gallium, or ex-situ doped using an ion implantation process. In some embodiments, a lightly doped epitaxial semiconductor layer is formed between the source/drain feature (232S, 232D) and the corresponding isolation dielectric layer 230, and the doping concentration of the lightly doped epitaxial semiconductor layer is lower than the doping concentration of the source/drain feature (232S, 232D).

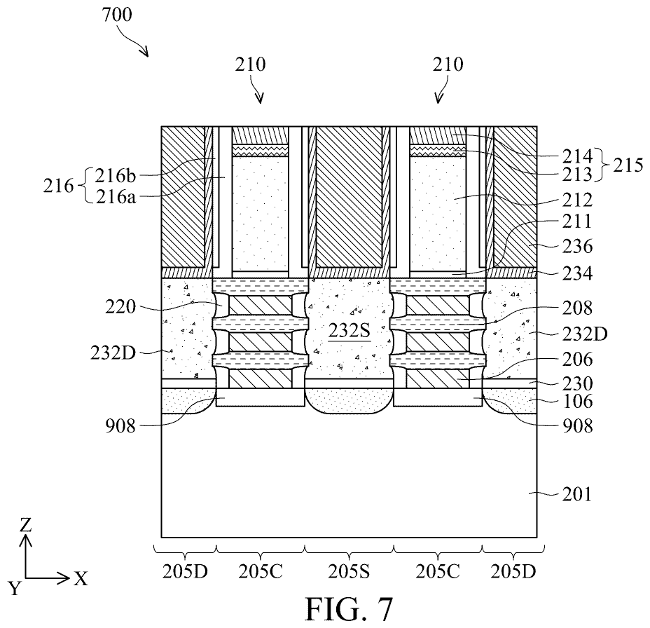

FIG. 7 is a structure formed from FIG. 6 and includes a contact etch stop layer (CESL) 234 and an interlayer dielectric (ILD) layer 236, according to various embodiments. The CESL 234 includes silicon nitride, silicon oxynitride, and/or similar materials and is formed by atomic layer deposition (ALD), plasma-enhanced chemical vapor deposition (PECVD), or other suitable deposition or oxidation processes. As shown in FIG. 7, the CESL 234 is deposited on top surfaces of the source feature 232S, the drain features 232D, and the sidewalls of the gate spacer layer 216. The ILD layer 236 is deposited by a PECVD process or another suitable deposition technique over the CESL 234. The ILD layer 236 is made from materials such as tetraethylorthosilicate (TEOS) oxide, undoped silicate glass, or doped silicon oxide, such as borophosphosilicate glass (BPSG), fused silica glass (FSG), phosphosilicate glass (PSG), boron-doped silicon glass (BSG), and/or other suitable dielectric materials. In some embodiments, after forming the ILD layer 236, the structure 700 is annealed to improve the integrity of the ILD layer 236.

FIG. 8 is a structure 800 formed from the structure 700 of FIG. 7, according to various embodiments. The structure 800 is formed by replacement of the sacrificial gate stacks 210 with the gate structures 240, according to various embodiments. A planarization process, such as a chemical mechanical polishing (CMP) process, is performed on the structure 700 to remove excessive materials and expose the top surfaces of the sacrificial gate electrode layer 212 in the sacrificial gate stacks 210. After the exposure of the sacrificial gate electrode layer 212, the next step is the removal of the sacrificial gate stacks 210 of the structure 700. The removal of the sacrificial gate stacks 210 includes one or more etching processes selective to the material in the sacrificial gate stacks 210. For example, the removal of the sacrificial gate stacks 210 is performed using a selective wet etch, a selective dry etch, or a combination thereof. After removing the sacrificial gate stacks 210, the sacrificial layers 206 are selectively removed to release the channel layers 208 in the channel regions 205C. The selective removal of the sacrificial layers 206 is implemented by a selective dry etch, a selective wet etch, or another selective etching process. In some embodiments, the selective wet etching includes an APM etch (e.g., an ammonium hydroxide-hydrogen peroxide-water mixture).

As shown in FIG. 8, each of the gate structures 240 includes a gate dielectric layer 242 and a gate electrode layer 244 over the gate dielectric layer 242. In some embodiments, the gate dielectric layer 242 includes an interfacial layer disposed on the channel layers 208 and a high-k dielectric layer over the interfacial layer. A high-k dielectric layer refers to a dielectric material with a dielectric constant greater than that of silicon dioxide, which is about 3.9. A low-k dielectric layer refers to a dielectric material with a dielectric constant no greater than that of silicon dioxide. In some embodiments, the interfacial layer includes silicon oxide. The high-k dielectric layer is then deposited over the interfacial layer using ALD, CVD, or other suitable methods. According to various embodiments, the high-k dielectric layer includes hafnium oxide. Alternatively, according to various embodiments, the high-k dielectric layer includes other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO₃, hafnium lanthanum oxide, lanthanum silicon oxide, aluminum silicon oxide, hafnium tantalum oxide, hafnium titanium oxide, (Ba, Sr)Ti₃ (BST), silicon nitride, silicon oxynitride, combinations thereof, or other suitable materials.

The gate electrode layer 244 is deposited over the gate dielectric layer 242 using ALD, PVD, CVD, e-beam evaporation, plating, or other suitable methods. The gate electrode layer 244 includes either a single layer or a multi-layer structure, such as various combinations of a metal layer with a selected work function to enhance device performance (work function metal layer), a liner layer, a wetting layer, an adhesion layer, a metal alloy, or a metal silicide. By way of example, the gate electrode layer 244 includes titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or combinations thereof. Further, in embodiments in which the structure 800 includes n-type and p-type transistors, different gate electrode layers are formed separately for the n-type and p-type transistors, with each layer including different work function metal layers (e.g., to provide different n-type and p-type work function metal layers).

FIG. 9A is a vertical cross-sectional view of a structure 900a that is used in the formation of a semiconductor device 900b and FIG. 9B is a vertical cross-sectional view of the semiconductor device 900b formed from the structure of FIG. 9A, according to various embodiments. The structure 900a is formed from the structure 800 of FIG. 8 by etching the ILD layer 236 to form a contact trench 902 through the ILD layer 236 thereby exposing the source/drain structure 232. The source/drain feature 232 is then doped by performing an implantation process to generate a heavily doped region 904.

For example, in some embodiments, the heavily doped region 904 is doped with n-type or p-type dopant to a concentration that is between about 5×10²⁰ atom/cm³ and about 1×10²² atom/cm while the remainder of the source/drain feature 232 is doped with a same-type conductivity dopant but with a lower concentration that is between about 5×10¹⁹ atom/cm³ and about 3×10²¹ atom/cm. As described above, the first epitaxial layer 106 is undoped in some embodiments. As shown in FIGS. 9A and 9B, the source/drain feature 232 need not completely fill the space above the isolation dielectric layer 230 and, in certain embodiments, one or more voids 906 are formed between the isolation dielectric layer 230 and the source/drain feature 232. According to certain embodiments, the structure 900a and the semiconductor device 900b further includes a second isolation dielectric layer 908 formed between the substrate and a bottom surface of the gate structure 240 as described above with reference to FIGS. 1A to 8. According to various embodiments, the second isolation dielectric layer 908 includes materials similar to those of the isolation dielectric layer 230.

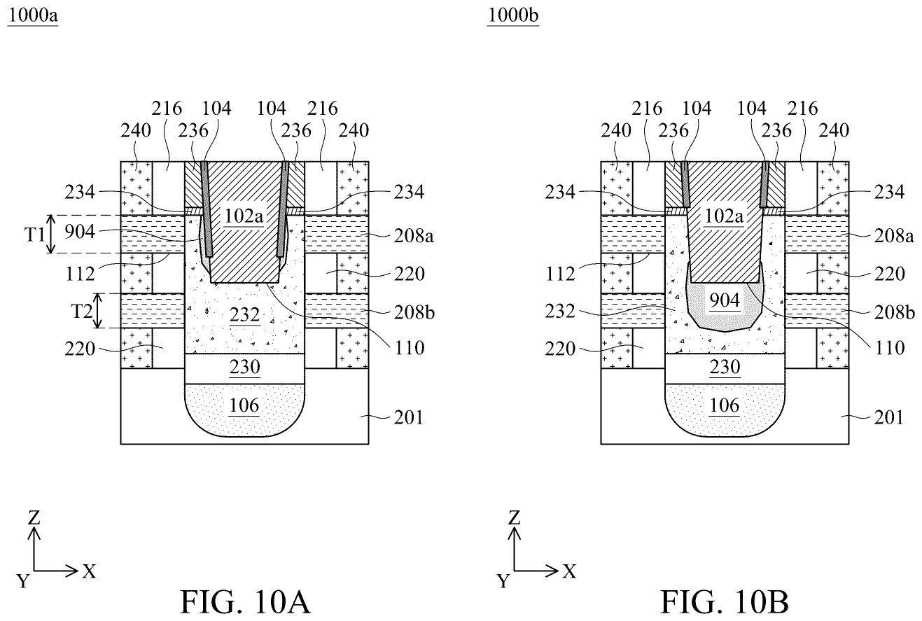

In some embodiments, the contact trench 902 is filled with a conductive material to form a front contact 102a (not shown) that is in contact with the heavily doped region 904 of the source/drain feature 232. In other embodiments, the source/drain feature 232 is further etched to form an extended contact trench 903 (e.g., see FIG. 9C), which is then filled with the conductive material to form the front contact 102a, as shown in FIG. 9B. According to various embodiments, a liner layer 104 is formed in the contact trench 902. The liner layer 104 includes silicon nitride or other material that acts as a barrier between the front contact 102a and the ILD layer 236. For example, in some embodiments, the liner layer 104 includes Si₃N₄, SiN, SiO₂, SiON, SiCN, SiCON, SiCO, or a high-k dielectric such as HfO₂, ZrO₂, Al₂O₃, TiO₂, La₂O₃, Y₂O₃, BaSrTiO₃, or the like. In some embodiments, the liner layer 104 is also formed in the extended contact trench 903 such that the liner layer 104 extends below the bottom surface 112 of the first channel layer 208a (e.g., see FIG. 10A). Alternatively, in some embodiments, the liner layer 104 is formed only over the contact trench 902 such that the liner layer 104 lies above a top surface 113 of the first channel layer 208a, as shown in FIG. 9B.

According to various embodiments, the semiconductor device 900b further includes a silicide layer 120 formed between the source/drain feature 232 and the front contact 102a as shown in FIG. 9B. The silicide layer 120 is formed over the source/drain feature 232 in some embodiments as follows. A thin layer of a metal (not shown), such as titanium, tantalum, cobalt, tungsten, or nickel, is deposited onto the source/drain feature 232 (e.g., over surfaces of the extended contact trench 903 in FIG. 9C) and the surrounding areas. This metal layer is then subjected to a rapid thermal annealing process, during which it reacts with the underlying silicon or SiGe layer to form the silicide layer 120. The choice of metal and the annealing conditions are controlled to optimize the formation of the desired silicide phase, such as titanium silicide, cobalt silicide, or nickel silicide, which exhibits lower resistivity than the source/drain features and stable electrical characteristics.

After the formation of the silicide layer 120, any unreacted metal and metal silicide is removed from non-relevant areas in some embodiments, for example, by a selective etching process. This results in a highly conductive silicide layer 120 directly in contact with the source/drain feature 232. As such, the presence of the silicide layer 120 provides a highly conductive contact with the front contact 102a that is subsequently formed. Alternatively, in some embodiments, the selective etching process is omitted and a thin layer of the metal is left on exposed surfaces of the ILD layer 236 (not shown) before the formation of the front contact 102a.

According to various embodiments, the front contact 102a is then formed by depositing a conductive material over the silicide layer 120 within the contact trench 902 and the extended contact trench 903 (e.g., see FIG. 9C). According to various embodiments, the conductive material is a combination of a metallic liner layer (such as a metallic nitride or a metallic carbide) and a metallic fill material. Each metallic liner layer includes one or more TiN, TaN, WN, TiC, TaC, or WC, and each metallic fill material portion includes W, Cu, Al, Co, Ru, Mo, Ta, Ti, alloys thereof, and/or combinations thereof. Other suitable metallic liner and metallic fill materials are within the contemplated scope of this disclosure and may also be used.

As described above, the front contact 102a is configured as a source/drain contact having a bottom surface 110 that is lower than a bottom surface 112 of the first channel layer 208a. Conductive contact between the front contact 102a and the source/drain feature 232 is improved by placing the front contact 102a below the first channel layer 208a, which thereby improves the electrical conductivity of the source/drain contact. In this regard, contact resistance is lowered which leads to an increase in device performance in the form of decreased resistive losses and reduced RC delays. However, placing the front contact 102a below the first channel layer 208a introduces increased electric field strengths in the vicinity of the second channel layer 208b, which may lead to increased short-channel effects and DIBL effects.

Other effects include dopant encroachment from the heavily doped region 904 into one or more channel regions (208a, 208b, 208c) which alters electrostatic field distributions that can lead to undesirable effects. Dopant encroachment and short-channel effects are related but distinct phenomena. Short-channel effects refer to a set of issues that become more pronounced as the transistor's channel length decreases. These effects include threshold voltage roll-off, and subthreshold slope degradation, which all occur due to the weakened electrostatic control the gate structure 240 has over the channel layers (208a, 208b, 208c) as the device shrinks. Dopant encroachment, on the other hand, occurs when dopant atoms from the source/drain feature 232 unintentionally diffuse into the channel layers (208a, 208b, 208c). This can exacerbate short-channel effects by altering the doping profile of the channel, especially near junctions, which can lead to unintended high or low doping concentrations.

These changes make the device more susceptible to issues like DIBL, where the drain voltage lowers the potential barrier at the source-channel junction, allowing current to flow even when the transistor is supposed to be off. Additionally, dopant encroachment can reduce electrostatic control by making regions of the channel more conductive, increasing leakage current. This worsens threshold voltage roll-off, where the threshold voltage decreases as the channel length shortens. Thus, while short-channel effects are primarily due to the challenges of controlling a transistor at small dimensions, dopant encroachment contributes by disturbing a doping profile of the channel, further exacerbating the loss of gate control, and increasing leakage currents, ultimately degrading the device's performance in smaller nodes.

According to various embodiments, these effects are mitigated by decreasing the thickness T2 of the second channel layer 208b relative to the thickness T1 of the first channel layer 208a, as mentioned above. In this regard, the plurality of channel layers (208a, 208b, 208c) in FIG. 9B have respective thicknesses (T1, T2, T3). According to various embodiments, a first thickness T1 of a first channel layer 208a is thicker than a second thickness T2 of a second channel layer 208b. The choice of different channel thicknesses reduces DIBL effects and improves the conductivity of the channel layers (208a, 208b, 208c). For example, channel layers near regions of lower dopant concentrations have a greater thickness to reduce resistance, and channel layers near regions of higher dopant concentrations have a reduced thickness to decrease DIBL effects.

In certain configurations, there may be fewer dopant atoms near the first channel layer 208a which increases a relative resistivity of the portion of the source/drain feature 232 near the first channel layer 208a. This can occur because the heavily doped region 904 is partially removed in forming the extended contact trench 903 (e.g., compare FIGS. 9A and 9B). Alternatively, as described in greater detail with reference to FIG. 9D, below, the heavily doped region 904 is formed at a lower depth in the source/drain feature 232 and, as such, there are fewer dopant atoms near the first channel layer 208a. In both situations, the conductivity of the first channel layer 208a is improved by increasing the first thickness T1 of the first channel layer 208a relative to the second thickness T2 of the second channel layer 208b. Similarly, channel layers (e.g., the second channel layer 208b) that are near a region of higher doping (e.g., see heavily doped region 904 in FIGS. 9C and 9D) are configured to have a relatively smaller thickness T2 to reduce DIBL effects.

According to certain embodiments, each of the first thickness T1 and the second thickness is between about 2 nm and about 10 nm, and a difference between the first thickness T1 and the second thickness T2 is between about 0.5 nm and about 5 nm. Also, according to various embodiments, the third thickness T3 (i.e., the thickness T3 of the third channel layer 208c) is comparable to the first thickness T1 and the second thickness T2 but may have various values relative to the first thickness T1 and the second thickness T2. For example, the third thickness T3 may also be between about 2 nm and about 10 nm. According to various embodiments, the thicknesses (T1, T2, T3) may be ordered in different ways, such as T1>T2=T3; T1=T3>T2; T1>T3>T2; and so on.

FIG. 9C is a vertical cross-sectional view of a structure 900c that is used in the formation of a semiconductor device 900d, and FIG. 9D is a vertical cross-sectional view of the semiconductor device 900d formed from the structure 900c of FIG. 9C, according to various embodiments. In this regard, the processes used to form the semiconductor device 900d are similar to processes used to form the semiconductor device 900b with the exception that the heavily doped region 904 is formed after etching the source/drain feature 232 to form the extended contact trench 903. As such, the heavily doped region 904 in the structure 900c extends to a greater depth than the heavily doped region 904 of FIGS. 9A and 9B. This configuration, in which the heavily doped region 904 is deeper within the source/drain feature 232 may have different electrical characteristics than the configuration of FIGS. 9A and 9B in certain embodiments. For example, the front contact 102a formed in the semiconductor device 900d may have a different contact resistance and corresponding RC delays relative to certain embodiments in which the heavily doped region 904 is placed at a reduced depth. As such, these different configurations provide flexibility in circuit design such that electrical characteristics can be optimized by modifying the depth and doping concentration of the heavily doped region 904. Also, as further shown in FIGS. 9C and 9D, the second isolation dielectric layer 908 is omitted in certain embodiments.

As described above, the lower placement of the heavily doped region 904 tends to increase electric field strengths near the second channel layer 208b relative to the first channel layer 208a, which may lead to increased short-channel and DIBL effects governing the electrical characteristics of the second channel layer 208b relative to the electrical characteristics of the first channel layer 208a. Further, the position of the heavily doped region 904 may lead to increased dopant encroachment into the second channel layer 208b. To mitigate such effects, the second thickness T2 is chosen be less than that of the first thickness T1 of the first channel layer 208a. The relative thicknesses and ordering of the various thicknesses (T1, T2, T3) are similar to those of the embodiments described above with reference to FIGS. 9A and 9B, described above. For example, each of the thicknesses (T1, T2, T3) is between about 2 nm and about 10 nm, and a difference between the first thickness T1 and the second thickness T2 is between about 0.5 nm and about 5 nm. Further, according to various embodiments, the thicknesses (T1, T2, T3) are ordered in different ways in respective embodiments, such as T1>T2=T3; T1=T3>T2; T1>T3>T2; and so on.

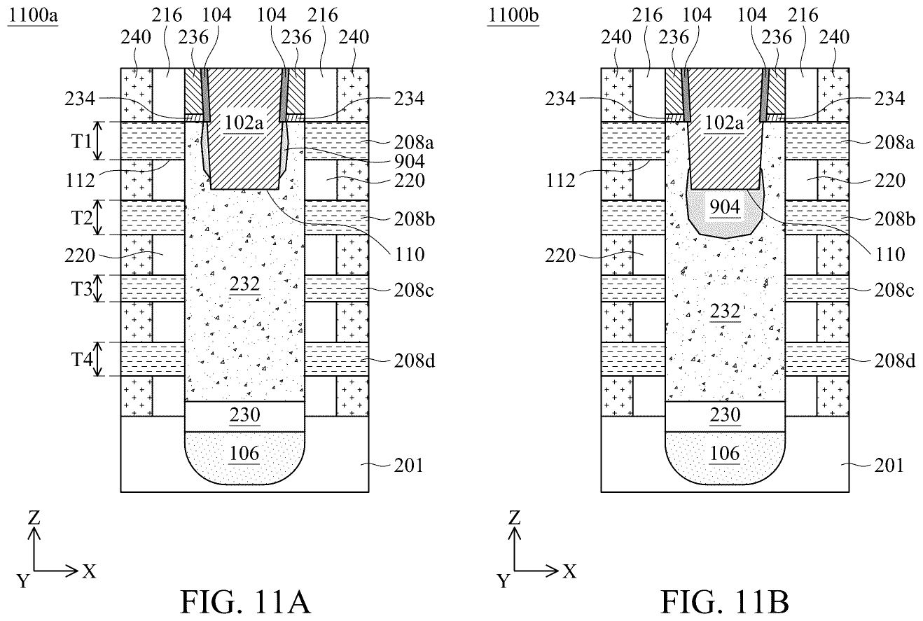

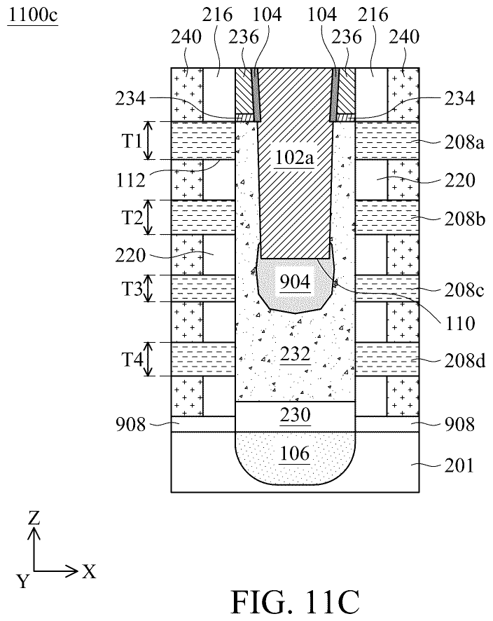

FIGS. 10A to 11C are vertical cross-sectional views of respective semiconductor devices (1000a, 1000b, 1100a, 1100b, 1100c) having different numbers of channel layers, according to various embodiments. In this regard, the semiconductor devices (1000a, 1000b) of FIGS. 10A and 10B include two channel layers (208a, 208b) and the semiconductor devices (1100a, 1100b, 1100c) of FIGS. 11A, 11B, and 11C include four channel layers (208a, 208b, 208c, 208d). In each of the respective semiconductor devices (1000a, 1000b, 1100a, 1100b, 1100c), the thicknesses (T1, T2, T3, T4) are adjusted relative to the depth of the front contact 102a and relative to the depth of the heavily doped region 904 to improve device characteristics.

As described above, the liner layer 104 can be configured to extend below a bottom surface 112 of the first channel layer 208a, as shown in FIG. 10A. Alternatively, the liner layer 104 can be configured to only extend to a depth that is above a top surface 113 of the first channel layer 208a, as shown in FIG. 10B. Also, as described above, the heavily doped region 904 is placed at various depths in different embodiments. For example, as shown in FIG. 10A, the heavily doped region 904 of the semiconductor device 1000a is located above the heavily doped region 904 of the semiconductor device 1000b of FIG. 10B. The placement of the heavily doped region 904, as well as other design considerations, such as the number of channel layers (208a, 208b) and the thicknesses (T1, T2) of the channel layers (208a, 208b) are chosen based on specific applications and can be optimized through the use of numerical simulation techniques. In some embodiments, there are more than four channel layers in the semiconductor device.

In each of the embodiments of FIGS. 10A to 11C, the thinnest channel layer (208b, 208c) is the channel layer closest to the heavily doped region 904 and/or closest to the front contact 102a to reduce short-channel and DIBL effects. Similarly, thicknesses of channel layers that are farther away from the heavily doped region 904 and/or the front contact 102a are adjusted to be relatively thicker to reduce contact resistance and RC delays associated with corresponding channel layers. For example, in the semiconductor device 1100b of FIG. 11B, the second channel layer 208b has the smallest thickness T2, while in the semiconductor device 1100c of FIG. 11C, the third channel layer 208c has the smallest thickness T3. In embodiments with greater numbers of channel layers (208a, 208b, 208c, 208d) there are a greater number of combinations for ordering the various thicknesses (T1, T2, T3, T4).

For example, the semiconductor devices (1100a, 1100b) of FIGS. 11A and 11B each are ordered as T1>T2=T3=T4 in some embodiments. In other embodiments, the semiconductor device 1100b of FIG. 11B is ordered T1=T3=T4>T2 or as T1>T3=T4<T2. In other embodiments, the semiconductor device 1100c of FIG. 11C is ordered as T1=T2=T4>T3. As can be seen from these examples, many design choices can be made based on the number of channel layers and the depth of the heavily doped region 904 and the front contact 102a. The various thicknesses and ordering of thicknesses can be optimized for increased device performance, for example, based on the results of numerical simulations in which optimization algorithms are applied.

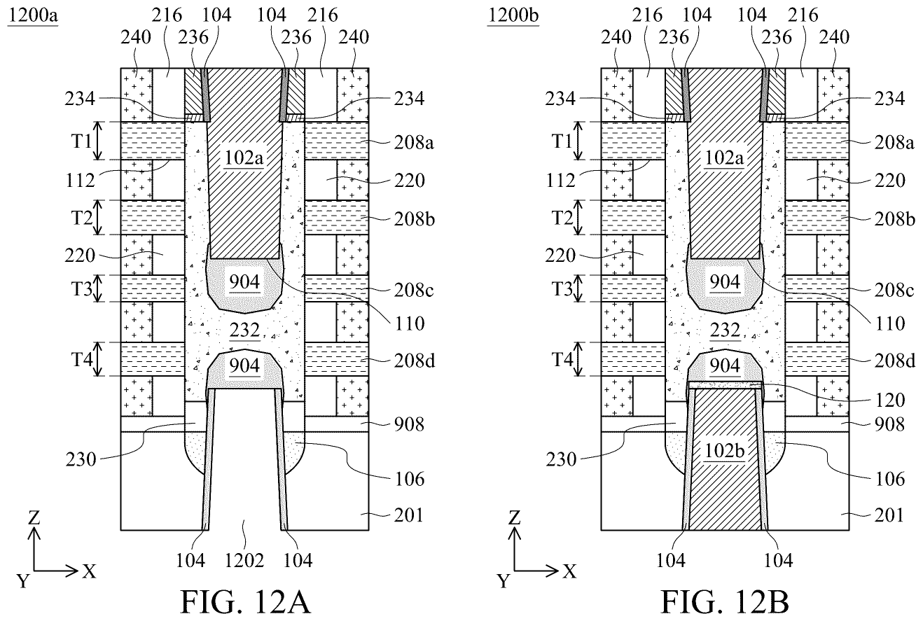

FIG. 12A is a vertical cross-sectional view of a structure 1200a used in forming a semiconductor device 1200b having a backside contact 102b, and FIG. 12B is a vertical cross-sectional view of the semiconductor device 1200b formed from the structure 1200a of FIG. 12A, according to various embodiments. The structure 1200a is formed from the semiconductor device 1100c by etching a backside trench 1202 through the substrate 201, the undoped semiconductor layer 106, the first isolation dielectric layer 230, and a backside portion of the source/drain structure 232. As shown in FIG. 12A, according to some embodiments, an implantation operation is performed to generate an additional heavily doped region 904 within a lower portion of the source/drain feature 232.

Liner layers 104 are then deposited over sidewalls of the backside trench 1202 in some embodiments. The backside contact 102b is then formed by depositing a conducting material over liner layers 104. The processes used to form the backside contact 102b are similar to those used to form the front contact 102a. According to various embodiments, a silicide layer 102 is formed between the heavily doped region 904 and the backside contact 102b using processing operations similar to those described above. According to various embodiments, a further silicide layer 120 is also formed between the front contact 102a and the drain feature 232.

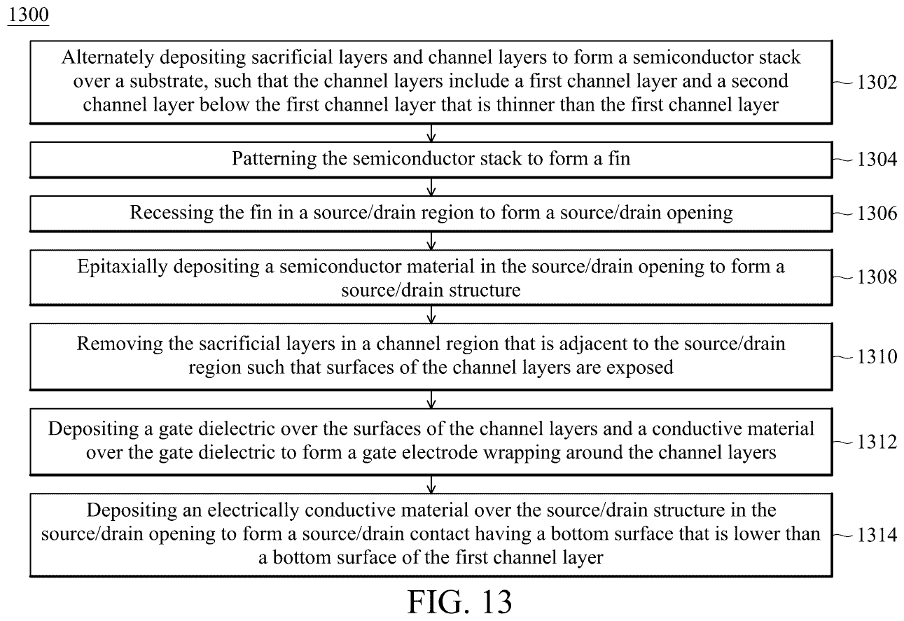

FIG. 13 is a flowchart illustrating operations of a method 1300 of manufacturing a semiconductor device (100, 900b, 900d, 1000a, 1000b, 1100a, 1100b, 1100c, 1200b), according to various embodiments. According to operation 1302, the method 1300 includes alternately depositing sacrificial layers 206 and channel layers 208 to form a semiconductor stack (206, 208) over a substrate 201, such that the channel layers 208 include a first channel layer 208a and a second channel layer 208b below the first channel layer 208a that is thinner than the first channel layer 208a. According to operation 1304, the method 1300 includes patterning the semiconductor stack 205 to form a fin 205. According to operation 1306, the method 1300 includes recessing the fin 205 in a source/drain region (205S, 205D) to form a source/drain opening (218S, 218D). According to operation 1308, the method 1300 includes epitaxially depositing a semiconductor material in the source/drain opening (218S, 218D) to form a source/drain structure 232.

According to operation 1310, the method 1300 includes removing the sacrificial layers 206 in a channel region 205C that is adjacent to the source/drain region (205S, 205D) such that surfaces of the channel layers 208 are exposed. According to operation 1312, the method 1300 includes depositing a gate dielectric 242 over the surfaces of the channel layers 208 and a conductive material over the gate dielectric 242 to form a gate electrode 244 wrapping around the channel layers 208. According to operation 1314, the method 1300 includes depositing an electrically conductive material over the source/drain structure 232 in the source/drain opening (218S, 218D) to form a source/drain contact 102 having a bottom surface 110 that is lower than a bottom surface 112 of the first channel layer 208a.

According to various embodiments, the method 1300 further includes epitaxially depositing an undoped semiconductor layer 106 over a surface of the source/drain opening (218S, 218D), and depositing a first isolation dielectric layer 230 over the undoped semiconductor layer 106, before epitaxially depositing the semiconductor material to form the source/drain structure 232. According to various embodiments the first channel layer 208a has a first thickness T1 and the second channel layer 208b has a second thickness T2 that is between about 2 nm and about 10 nm, and a difference between the first thickness T1 and the second thickness T2 that is between about 0.5 nm and about 5 nm.

According to various embodiments, the method 1300 further includes depositing an interlayer dielectric layer 236 over the source/drain structure 232, etching the interlayer dielectric layer 236 to form a contact trench 902 through the interlayer dielectric layer 236 thereby exposing the source/drain structure 232, etching the source/drain structure 232 through the contact trench 902 to form an extended contact trench 903, performing an implantation operation to form a doped region 904 in the source/drain structure 232 through the extended contact trench 903, and forming the source/drain contact 102 in the extended contact trench 903 over the source/drain structure 232. According to various embodiments, the method 1300 further includes forming a liner layer 104 on sidewalls of the contact trench 902 before etching the source/drain structure 232, forming a silicide layer 120 over the doped region 904, and forming the source/drain contact 102 over the silicide layer 120.

According to various embodiments, alternately depositing the sacrificial layers 206 and the channel layers 208 to form the semiconductor stack 205 further includes depositing at least three channel layers (208a, 208b, 208c) such that a third channel layer 208c is formed below the second channel layer 208b. According to various embodiments, the at least three channel layers (208a, 208b, 208c) includes a thinnest channel layer (208b, 208c) that is closest to the doped region 904. According to various embodiments, the method 1300 further includes forming a second isolation dielectric layer 908 between the substrate 201 and a bottom surface of the gate electrode 244, and in various embodiments, the first isolation dielectric layer 230 and the second isolation dielectric layer 908 include one or more of a silicon nitride, a silicon oxide, a silicon oxynitride, a silicon carbon nitride, a silicon carbon oxide, or a high-k dielectric including one or more of HfO2, ZrO₂, Al₂O₃, TiO₂, La₂O₃, Y₂O₃, BaSrTiO₃.

According to various embodiments, the method 1300 further includes etching a backside trench 1202 through the substrate 201, through the undoped semiconductor layer 106, the first isolation dielectric layer 230, and a backside portion of the source/drain structure 232, and depositing a conductive material into the backside trench 1202 to form a backside source/drain contact 102b. According to various embodiments, a void 906 is formed between a bottom of the source/drain structure 232 and a top of the first isolation dielectric layer 230.

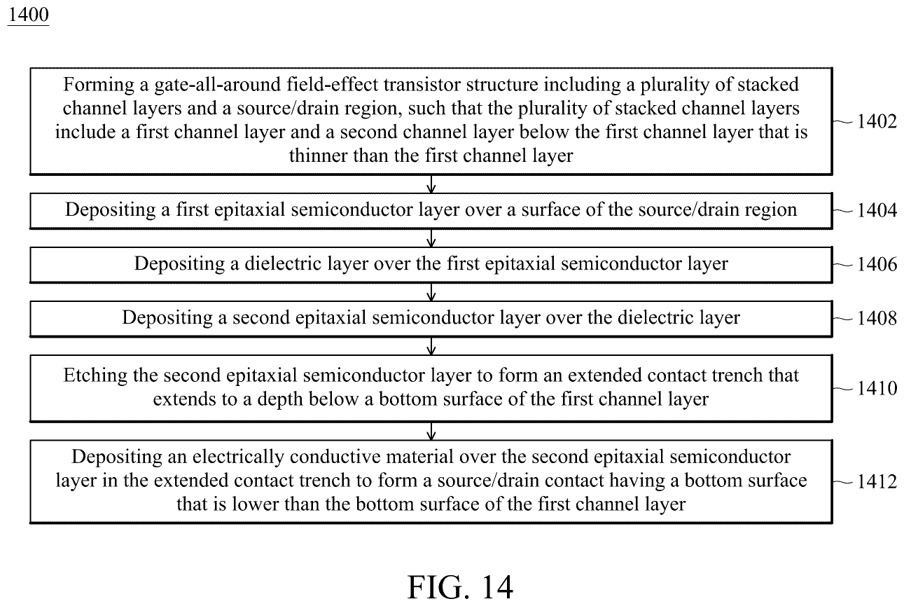

FIG. 14 is a flowchart illustrating operations of a method 1400 of manufacturing a semiconductor device (100, 900b, 900d, 1000a, 1000b, 1100a, 1100b, 1100c, 1200b), according to various embodiments. According to operation 1402, the method 1400 includes forming a gate-all-around field-effect transistor 100 structure including a plurality of stacked channel layers (208a, 208b, 208c) and a source/drain region (205S, 205D), such that the plurality of stacked channel layers 208 include a first channel layer 208a and a second channel layer 208b below the first channel layer 208a that is thinner than the first channel layer 208a. According to operation 1404, the method 1400 includes depositing a first epitaxial semiconductor layer 106 over a surface of the source/drain region (205S, 205D). According to operation 1406, the method 1400 includes depositing a dielectric layer 230 over the first epitaxial semiconductor layer 106. According to operation 1408, the method 1400 includes depositing a second epitaxial semiconductor layer 232 over the dielectric layer 230.

According to operation 1410, the method 1400 includes etching the second epitaxial semiconductor layer 232 to form an extended contact trench 903 that extends to a depth below a bottom surface of the first channel layer 208a. According to operation 1412, the method 1400 includes depositing an electrically conductive material over the second epitaxial semiconductor layer 232 in the extended contact trench 903 to form a source/drain contact 102 having a bottom surface 110 that is lower than the bottom surface 112 of the first channel layer 208a.

According to various embodiments, the method 1400 further includes performing an implantation operation to form a doped region 904 in the second epitaxial semiconductor layer 232 through the extended contact trench 903 before depositing the electrically conductive material over the second epitaxial semiconductor layer 232 such that there is a heavily doped region 904 below the extended contact trench 903, forming a silicide layer 120 over the doped region 904, and depositing the electrically conductive material over the silicide layer 120. According to various embodiments, epitaxially depositing the first epitaxial semiconductor layer 106 further includes depositing undoped Si or SiGe. According to various embodiments, the method 1400 further includes depositing a liner layer 104 layer over sidewalls of the extended contact trench 903, before depositing the electrically conductive material, such that the liner layer 104 layer extends below the bottom surface of the first channel layer 208a.

According to various embodiments, the method 1400 further includes depositing a liner layer 104 layer over sidewalls of the source/drain region (205S, 205D), before etching the second epitaxial semiconductor layer 232 to form the extended contact trench 903, such that the liner layer 104 layer extends to a depth that is above a top surface 113 of the first channel layer 208a. According to various embodiments, the plurality of stacked channel layers 208 includes at least three channel layers (208a, 208b, 208c) having a thinnest channel layer (208b, 208c) that is closest to the doped region 904.

Referring to all drawings and according to various embodiments of the present disclosure, a semiconductor device (100, 900b, 900d, 1000a, 1000b, 1100a, 1100b, 1100c, 1200b) is provided. The semiconductor device (100, 900b, 900d, 1000a, 1000b, 1100a, 1100b, 1100c, 1200b) includes a plurality of stacked channel layers (208a, 208b, 208c, 208d) and a source/drain region (205S, 205D), wherein the plurality of stacked channel layers 208 include a first channel layer 208a and a second channel layer 208b below the first channel layer 208a that is thinner than the first channel layer 208a, a source/drain structure 232 including a first epitaxial semiconductor layer 232 formed over the source/drain region (205S, 205D) such that the source/drain structure 232 is in contact with the plurality of stacked channel layers 208, and a source/drain contact 102 formed over the source/drain structure 232 such that a bottom surface 110 of the source/drain contact 102 is lower than a bottom surface 112 of the first channel layer 208a.

According to various embodiments, the semiconductor device (100, 900b, 900d, 1000a, 1000b, 1100a, 1100b, 1100c, 1200b) further includes a second epitaxial semiconductor layer 106 formed below the first epitaxial semiconductor layer 232 and an isolation dielectric layer 230 formed between the first epitaxial semiconductor layer 232 and the second epitaxial semiconductor layer 106. According to various embodiments, the semiconductor device (100, 900b, 900d, 1000a, 1000b, 1100a, 1100b, 1100c, 1200b) further includes a doped portion 904 of the first epitaxial semiconductor layer 232 located below the bottom surface 110 of the source/drain contact 102. According to various embodiments, the plurality of stacked channel layers 208 includes at least three channel layers (208a, 208b, 208c) having a thinnest channel layer (208b, 208c) that is closest to the doped portion 904, and the plurality of stacked channel layers 208 are nanosheets or nanowires.

According to various embodiments, the semiconductor device (100, 900b, 900d, 1000a, 1000b, 1100a, 1100b, 1100c, 1200b) further includes a liner layer 104 layer formed over sidewalls of the source/drain region (205S, 205D) such that the liner layer 104 layer extends to a depth that is below the bottom surface 110 of the first channel layer 208a (e.g., see FIG. 10A), and a silicide layer 120 formed between the doped portion 904 of the first epitaxial semiconductor layer 232 and the bottom surface 110 of the source/drain contact 102.

One or more of the disclosed embodiments advantageously discloses methods of manufacturing a semiconductor device (100, 900b, 900d, 1000a, 1000b, 1100a, 1100b, 1100c, 1200b) having increased source/drain conductivity, reduced short-channel effects, and reduced drain-induced barrier lowering effects. In this regard, an embodiment semiconductor device (100, 900b, 900d, 1000a, 1000b, 1100a, 1100b, 1100c, 1200b) is configured as a gate-all-around transistor structure in which a source/drain contact 102 is formed in a source/drain epitaxial layer 232 such that the source/drain contact 102 has a bottom surface 110 that is lower than a bottom surface 112 of one or more channel layers (208a, 208b, 208c, 208d). The semiconductor device (100, 900b, 900d, 1000a, 1000b, 1100a, 1100b, 1100c, 1200b) further includes a heavily doped region 904 formed below the bottom surface 110 of the source/drain contact 102. Configuring the source/drain contact 102 and the heavily doped region 904 in this way increases the source/drain conductivity and thus reduces ohmic loss and RC delay. To avoid short-channel effects and drain-induced barrier lowering effects, a channel layer (208b, 208c) that is closest to the heavily doped region 904 and/or closest to the bottom surface 112 of the source/drain contact 102 has a thickness (T2, T3) that is smaller than that of other channel layers.

According to various embodiments, a method of manufacturing a semiconductor device includes alternately depositing sacrificial layers and channel layers to form a semiconductor stack over a substrate, such that the channel layers include a first channel layer and a second channel layer below the first channel layer that is thinner than the first channel layer, patterning the semiconductor stack to form a fin, recessing the fin in a source/drain region to form a source/drain opening, and epitaxially depositing a semiconductor material in the source/drain opening to form a source/drain structure. The method further includes removing the sacrificial layers in a channel region that is adjacent to the source/drain region such that surfaces of the channel layers are exposed, depositing a gate dielectric over the surfaces of the channel layers and a conductive material over the gate dielectric to form a gate electrode wrapping around the channel layers, and depositing an electrically conductive material over the source/drain structure in the source/drain opening to form a source/drain contact having a bottom surface that is lower than a bottom surface of the first channel layer.

According to various embodiments, the method further includes epitaxially depositing an undoped semiconductor layer over a surface of the source/drain opening and depositing a first isolation dielectric layer over the undoped semiconductor layer, before epitaxially depositing the semiconductor material, to form the source/drain structure. According to various embodiments, the first channel layer has a first thickness and the second channel layer has a second thickness that is each between 2 nm and 10 nm, and a difference between the first thickness and the second thickness is between 0.5 nm and 5 nm.

According to various embodiments, the method further includes depositing an interlayer dielectric layer over the source/drain structure, etching the interlayer dielectric layer to form a contact trench through the interlayer dielectric layer thereby exposing the source/drain structure, etching the source/drain structure through the contact trench to form an extended contact trench, performing an implantation operation to form a doped region in the source/drain structure through the extended contact trench, and forming the source/drain contact in the extended contact trench over the source/drain structure. According to various embodiments, the method further includes forming a liner on sidewalls of the contact trench before etching the source/drain structure, forming a silicide layer over the doped region, and forming the source/drain contact over the silicide layer.

According to various embodiments, alternately depositing the sacrificial layers and the channel layers to form the semiconductor stack further includes depositing at least three channel layers such that a third channel layer is formed below the second channel layer. According to various embodiments, the at least three channel layers include a thinnest channel layer that is closest to the doped region. According to various embodiments, the method further includes forming a second isolation dielectric layer between the substrate and a bottom surface of the gate electrode. According to various embodiments, the first isolation dielectric layer and the second isolation dielectric layer include one or more of silicon nitride, silicon oxide, silicon oxynitride, silicon carbon nitride, silicon carbon oxide, or a high-k dielectric including one or more of HfO2, ZrO₂, Al₂O₃, TiO₂, La₂O₃, Y₂O₃, BaSrTiO₃.

According to various embodiments, the method further includes etching a backside trench through the substrate, through the undoped semiconductor layer, the first isolation dielectric layer, and a backside portion of the source/drain structure, and depositing a conductive material into the backside trench to form a backside source/drain contact. According to various embodiments, a void is formed between a bottom of the source/drain structure and a top of the first isolation dielectric layer.

According to various embodiments, a method of manufacturing a semiconductor device includes forming a gate-all-around field-effect transistor structure including a plurality of stacked channel layers and a source/drain region, wherein the plurality of stacked channel layers include a first channel layer and a second channel layer below the first channel layer that is thinner than the first channel layer, depositing a first epitaxial semiconductor layer over a surface of the source/drain region, depositing a dielectric layer over the first epitaxial semiconductor layer, and depositing a second epitaxial semiconductor layer over the dielectric layer. According to various embodiments, the method further includes etching the second epitaxial semiconductor layer to form an extended contact trench that extends to a depth below a bottom surface of the first channel layer and depositing an electrically conductive material over the second epitaxial semiconductor layer in the extended contact trench to form a source/drain contact having a bottom surface that is lower than the bottom surface of the first channel layer.

According to various embodiments, the method further includes performing an implantation operation to form a doped region in the second epitaxial semiconductor layer through the extended contact trench before depositing the electrically conductive material over the second epitaxial semiconductor layer such that there is a heavily doped region below the extended contact trench, forming a silicide layer over the doped region, and depositing the electrically conductive material over the silicide layer. According to various embodiments, epitaxially depositing the first epitaxial semiconductor layer further includes depositing undoped Si or SiGe. According to various embodiments, the method further includes depositing a liner layer over sidewalls of the extended contact trench, before depositing the electrically conductive material, such that the liner layer extends below the bottom surface of the first channel layer.

According to various embodiments, the method further includes depositing a liner layer over sidewalls of the source/drain region, before etching the second epitaxial semiconductor layer to form the extended contact trench, such that the liner layer extends to a depth that is above a top surface of the first channel layer. According to various embodiments, the plurality of stacked channel layers includes at least three channel layers having a thinnest channel layer that is closest to the doped region.

According to various embodiments, a semiconductor device includes a plurality of spaced-apart stacked channel layers and a source/drain region, such that the plurality of stacked channel layers includes a first channel layer and a second channel layer below the first channel layer that is thinner than the first channel layer, a source/drain structure including a first epitaxial semiconductor layer formed over the source/drain region such that the source/drain structure is in contact with the plurality of stacked channel layers, and a source/drain contact formed over the source/drain structure such that a bottom surface of the source/drain contact is lower than a bottom surface of the first channel layer. According to various embodiments, the semiconductor device further includes a second epitaxial semiconductor layer formed below the first epitaxial semiconductor layer and a dielectric layer formed between the first epitaxial semiconductor layer and the second epitaxial semiconductor layer.

According to various embodiments, the semiconductor device includes a doped portion of the first epitaxial semiconductor layer located below the bottom surface of the source/drain contact. According to various embodiments, the plurality of stacked channel layers includes at least three channel layers having a thinnest channel layer that is closest to the doped portion, and the plurality of stacked channel layers are nanosheets or nanowires. According to various embodiments, the semiconductor device includes a liner layer formed over sidewalls of the source/drain region such that the liner layer extends to a depth that is below the bottom surface of the first channel layer and a silicide layer formed between the doped portion of the first epitaxial semiconductor layer and the bottom surface of the source/drain contact.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of manufacturing a semiconductor device, comprising:
alternately depositing sacrificial layers and channel layers to form a semiconductor stack over a substrate, wherein the channel layers comprise a first channel layer and a second channel layer below the first channel layer that is thinner than the first channel layer;
patterning the semiconductor stack to form a fin;
recessing the fin in a source/drain region to form a source/drain opening;
epitaxially depositing a semiconductor material in the source/drain opening to form a source/drain structure;
removing the sacrificial layers in a channel region that is adjacent to the source/drain region such that surfaces of the channel layers are exposed;
depositing a gate dielectric over the surfaces of the channel layers and a conductive material over the gate dielectric to form a gate electrode wrapping around the channel layers; and
depositing an electrically conductive material over the source/drain structure in the source/drain opening to form a source/drain contact having a bottom surface that is lower than a bottom surface of the first channel layer.

2. The method of claim 1, further comprising:
before epitaxially depositing the semiconductor material to form the source/drain structure:
epitaxially depositing an undoped semiconductor layer over a surface of the source/drain opening; and
depositing a first isolation dielectric layer over the undoped semiconductor layer.

3. The method of claim 1, wherein:
the first channel layer has a first thickness and the second channel layer has a second thickness;
each of the first thickness and the second thickness is between 2 nm and 10 nm; and
a difference between the first thickness and the second thickness is between 0.5 nm and 5 nm.

4. The method of claim 1, further comprising:
depositing an interlayer dielectric layer over the source/drain structure;
etching the interlayer dielectric layer to form a contact trench through the interlayer dielectric layer thereby exposing the source/drain structure;
etching the source/drain structure through the contact trench to form an extended contact trench;
performing an implantation operation to form a doped region in the source/drain structure through the extended contact trench; and
forming the source/drain contact in the extended contact trench over the source/drain structure.

5. The method of claim 4, further comprising:
forming a liner on sidewalls of the contact trench before etching the source/drain structure;
forming a silicide layer over the doped region; and
forming the source/drain contact over the silicide layer.

6. The method of claim 5, wherein alternately depositing the sacrificial layers and the channel layers to form the semiconductor stack further comprises depositing at least three channel layers such that a third channel layer is formed below the second channel layer.

7. The method of claim 6, wherein the at least three channel layers comprise a thinnest channel layer that is closest to the doped region.

8. The method of claim 2, further comprising:
forming a second isolation dielectric layer between the substrate and a bottom surface of the gate electrode,
wherein the first isolation dielectric layer and the second isolation dielectric layer comprise one or more of silicon nitride, silicon oxide, silicon oxynitride, silicon carbon nitride, silicon carbon oxide, or a high-k dielectric including one or more of HfO₂, ZrO₂, Al₂O₃, TiO₂, La₂O₃, Y₂O₃, BaSrTiO₃.

9. The method of claim 2, further comprising:
etching a backside trench through the substrate, through the undoped semiconductor layer, the first isolation dielectric layer, and a backside portion of the source/drain structure; and
depositing a conductive material into the backside trench to form a backside source/drain contact.

10. The method of claim 2, wherein a void is formed between a bottom of the source/drain structure and a top of the first isolation dielectric layer.

11. A method of manufacturing a semiconductor device, comprising:
forming a gate-all-around field-effect transistor structure comprising a plurality of stacked channel layers and a source/drain region, wherein the plurality of stacked channel layers comprise a first channel layer and a second channel layer below the first channel layer that is thinner than the first channel layer;
depositing a first epitaxial semiconductor layer over a surface of the source/drain region;
depositing a dielectric layer over the first epitaxial semiconductor layer;
depositing a second epitaxial semiconductor layer over the dielectric layer;
etching the second epitaxial semiconductor layer to form an extended contact trench that extends to a depth below a bottom surface of the first channel layer; and
depositing an electrically conductive material over the second epitaxial semiconductor layer in the extended contact trench to form a source/drain contact having a bottom surface that is lower than the bottom surface of the first channel layer.

12. The method of claim 11, further comprising:
performing an implantation operation to form a doped region in the second epitaxial semiconductor layer through the extended contact trench, before depositing the electrically conductive material over the second epitaxial semiconductor layer, such that there is a heavily doped region below the extended contact trench;
forming a silicide layer over the doped region; and
depositing the electrically conductive material over the silicide layer.

13. The method of claim 11, wherein epitaxially depositing the first epitaxial semiconductor layer further comprises depositing undoped Si or SiGe.

14. The method of claim 11, further comprising:
depositing a liner layer over sidewalls of the extended contact trench, before depositing the electrically conductive material, such that the liner layer extends below the bottom surface of the first channel layer.

15. The method of claim 11, further comprising:
depositing a liner layer over sidewalls of the source/drain region, before etching the second epitaxial semiconductor layer to form the extended contact trench, such that the liner layer extends to a depth that is above a top surface of the first channel layer.

16. The method of claim 12, wherein the plurality of stacked channel layers comprises at least three channel layers having a thinnest channel layer that is closest to the doped region.

17. A semiconductor device, comprising:
a plurality of spaced-apart stacked channel layers and a source/drain region, wherein the plurality of stacked channel layers comprise a first channel layer and a second channel layer below the first channel layer that is thinner than the first channel layer;
a source/drain structure comprising a first epitaxial semiconductor layer formed over the source/drain region such that the source/drain structure is in contact with the plurality of stacked channel layers; and
a source/drain contact formed over the source/drain structure such that a bottom surface of the source/drain contact is lower than a bottom surface of the first channel layer.

18. The semiconductor device of claim 17, further comprising:
a second epitaxial semiconductor layer formed below the first epitaxial semiconductor layer; and
a dielectric layer formed between the first epitaxial semiconductor layer and the second epitaxial semiconductor layer.

19. The semiconductor device of claim 17, further comprising:
a doped portion of the first epitaxial semiconductor layer located below the bottom surface of the source/drain contact, wherein:
the plurality of stacked channel layers comprises at least three channel layers having a thinnest channel layer that is closest to the doped portion, and
the plurality of stacked channel layers are nanosheets or nanowires.

20. The semiconductor device of claim 19, further comprising:
a liner layer formed over sidewalls of the source/drain region such that the liner layer extends to a depth that is below the bottom surface of the first channel layer; and
a silicide layer formed between the doped portion of the first epitaxial semiconductor layer and the bottom surface of the source/drain contact.
